(19) United States
(12) Patent Application Publication
(10) Pub. No.: US 2012/0024334 A1
(43) Pub. Date: Feb. 2, 2012

(54) Exhaust Heat Thermoelectric Generator (HETEG) System - Electric Power Generation Using the Combination of Thermoelectric Modules and Waste Exhaust Heat

(76) Inventor: CHARLES AMANZE, SOUTHFIELD, MI (US)

(21) Appl. No.: 12/845,786

(22) Filed: Jul. 29, 2010

(51) Int. Cl. H01L 35/30; H01L 35/28

(52) U.S. Cl. 136/212; 136/205

(57) ABSTRACT

The present invention pertains to a method for generating electric energy. For several good reasons, it is desired to reduce wastes and renew any wastes from fossil fuel engines. The exhaust heat thermoelectric generator (HETEG) used for this purpose according to the present invention can generate electrical energy from wasted heat emitting from said fossil fuel engine when combined with an array of thermoelectric modules and when said array is mounted on the periphery of a moving vehicle, or when said array is installed in a stationary location for idling trucks and semis to plug their exhaust tails into it. Further, said generated energy can be stored for reuse in any location.

### CROSS REFERENCE TO RELATED APPLICATIONS

THIS APPLICATION CLAIMS PRIORITY TO PROVISIONAL U.S. APPLICATION No. 61/274,407 FILED 17 Aug. 2009.

### STATEMENT REGARDING FEDERALLY SPONSORED RESEARCH OR DEVELOPMENT

Not Applicable

### REFERENCE TO SEQUENCE LISTING

Not Applicable

### BACKGROUND OF THE INVENTION

The present invention is in the technical field of waste energy recovery. More particularly, the present invention is in the technical field of using thermoelectric modules in collaboration with wasted exhaust heat emitting from fossil fuel engines to generate electric voltage.

When an engine is powered by fossil fuel (natural gas, coal, wood or crude oil), only about 30% of the fuel is used to perform useful work. The rest 70% are wasted. 32 to 35% are wasted in the form of exhaust heat while 35 to 38% are wasted Carbon Dioxide pollutants. Fossil fuel engines are only about 30% efficient.

One type of this invention will be installed on the sides or roof of a moving vehicle. Another type of this invention will also be installed on a stationary location so that idling vehicles can plug their exhaust tails into it to generate voltage. Many other types of this invention will be shown in the cause of this disclosure.

This invention will recover and reuse a large portion of the 32 to 35% wasted exhaust heat. This invention will also increase the efficiency of a fossil fuel engine from 30 to at least 45%.

A typical thermoelectric module has three main operating quantities. The quantities are hot temperature, cold temperature and voltage. When any two of the three quantities are adequately applied to the appropriate points on the thermoelectric module, the third quantity is produced. As an example, when adequate heat is applied to hot plate side and cold temperature is applied to cold plate side, voltage is generated in output terminals.

It is therefore not uncommon to generate electric power at the electrical terminals of a thermoelectric module with thermoelectric modules that have a substantial amount of figure of merit zT, and when there is a temperature difference between the hot plate side and cold plate side. (This temperature difference is also known as delta temperature dT). A significant amount of voltage is generated when a large delta temperature is present. Also, a larger amount of voltage is generated when many thermoelectric modules are connected together, in series or parallel arrangements.

Other inventors have attempted to generate electric energy with thermoelectric modules. The limitations experienced by prior arts are two folds; firstly, there is not an adequate thermal insulation that prevents heat escape from the hot plate side. In most prior arts, when heat is applied to the hot plate side, a significant amount of the applied heat escapes from the periphery of the hot plate side. Due to the close proximity of hot and cold plate sides, the escaped heat finds its way to the cold plate side. The escaped heat causes the cold plate side temperature to increase as undesired, therefore, reducing the value of delta temperature. A small delta temperature will result in a small generated voltage.

My present invention will insulate and isolate the hot plate side and prevent same from influencing the cold plate side.

The second limitation suffered by prior arts is the crowded space where the thermoelectric modules are installed. When used in an automotive, prior art thermoelectric generators are installed under a vehicle where there is too much competition for space with other vehicle parts. A crowded and limited space reduces the usable quantity and size of the thermoelectric modules, therefore limiting the amount of generated voltage. Moreover, in a crowded location such as under the vehicle, the cold side temperature will never be colder than the ambient temperature; in fact, the cold side temperature will be warmer than ambient temperature. As a result, thermoelectric devices will not function at their optimum when their cold side temperature is warmer than ambient.

My present invention overcomes the known limitations of prior arts by arranging a large number of thermoelectric modules in an array and in an unrestricted space before they are used on an automobile. When my present invention is used on the periphery of a moving machinery, wind gust will cool the cold side plate.

My present invention will, when mounted on the periphery (roof or sides) of a vehicle, generate enough energy such that vehicle alternator will not be needed any more. Further, extra energy will be generated for storage and future use by the same vehicle or by another. Moreover, the stored energy can be used in homes, camp sites, boats, factories and anywhere energy is needed.

My present invention will increase the miles per gallon fuel usage of any vehicle that uses my exhaust heat thermoelectric generator (HETEG) device without introducing additional aerodynamic drag, weight increase or engine load.

Another advantage of my present invention is, a plurality of said invention can be installed in a fixed location such as but not limited to truck stops, railway stations, ship docks, airports or factory sites, so that when vehicles such as but not limited to trucks, trains, ships or planes are stationary and idling, their exhaust tails can be connected into inlet pipes of said plurality of said invention at said stationary location.

Yet, another advantage of my present invention is, when installed on vehicles such as but limited to trucks, trains, ships or planes, and when said vehicles are stationary and idling in a location such as but not limited to truck stops, loading docks, railway stations, ship ports, airports or factory sites, output voltage of said invention can be connected to a network grid of other energy sources or to a charging station. Also, a stationary pool of water can be used boost the efficiency of my present invention.

Further, my present invention will reduce the quantity of Carbon Dioxide emitted into the atmosphere by fossil fuel engines, therefore, reducing greenhouse effect.

Further, my present invention will reduce our dependency on fossil fuel; therefore, cost of fossil fuel will drop, creating a positive economic and national security impact.

When the environment is less polluted as a result of my present invention, there will be a reduction in respiratory illness which will prolong the lives of our citizens and reduce medical expenses. Also, when national security of any nation is not threatened, regional conflicts will cease.

It is anticipated that my present HETEG device invention alone will introduce additional weight if used on a moving vehicle. However, if my HETEG device is used with the entire HETEG system, a significant weight reduction will be achieved. The HETEG system are:

1—a multi-element HETEG device,

2—an Exhaust Bypass System (EBS),

3—a meshed wire exhaust pipe sandwiched with thermal insulation, and

4—a Systems Control Unit.

Benefits and advantages of my present invention is not limited to the areas than I have listed.

### SUMMARY OF THE INVENTION

The present invention provides an improved system for generating electric energy by using the combination of wasted exhaust heat from fossil fuel engines and thermoelectric modules.

The method includes using a plurality of thermoelectric modules, together with exhaust heat from fossil fuel engines to generate electrical energy. The method also includes connecting several thermoelectric modules in an array of electrical series and parallel arrangements to achieve large output voltage and load current.

Further, the method includes conserving the exhaust heat from exhaust manifold, through the exhaust cylinder, up to the exhaust tail, by using a meshed sandwiched light weight exhaust pipe to convey exhaust heat into hot plate side of the plurality of thermoelectric modules.

The method further includes an exhaust bypass system (EBS) that serves three purposes, namely:
1. it protects the thermoelectric modules from heat damage by diverting the exhaust heat away from the HETEG device when a temperature sensor senses an excessive exhaust heat;
2. it turns the HETEG device ON by allowing exhaust heat to enter the HETEG device, and turns it OFF by preventing exhaust heat from entering the HETEG device; and,
3. it keeps output voltage relatively constant by regulating the quantity of exhaust heat entering HETEG device.

Further, the method includes channeling temperature of lower value, lower than the temperature used on the hot plate side, onto the cold plate side, therefore creating a large temperature difference between hot plate side and cold plate side of thermoelectric modules.

The method also includes connecting the electrical output voltages of a multi output

HETEG device to a voltage selection unit for processing into a desired value by connecting them in series and or parallel arrangements.

The method further includes connecting the electrical output of the voltage selector unit to a voltage stabilizer/charger unit such as Direct Current to Direct Current (DC-DC) converter.

The method further includes connecting the output of the DC-DC converter to an electrical load such as replace vehicle alternators or use to charge discharged batteries.

### BRIEF DESCRIPTION OF THE DRAWING

The drawings illustrate several preferred embodiments of the invention with same numerical referring to similar parts throughout the several views, wherein:

FIG. 1 is a HETEG system showing electrical and mechanical connections.

FIG. 2 is a HETEG device mounted on the side of a truck.

FIG. 3A is a side view of a HETEG system mounted on the roof of a mini-van.

FIG. 3B is a front view of a HETEG system mounted on the roof of a mini-van.

FIG. 3C is a top view of a HETEG system mounted on the roof of a mini-van.

FIG. 3D is a back view of a HETEG system mounted on the roof of a mini-van.

FIG. 4 is a pictorial view of several stationary HETEG systems ready for exhaust pipes of idling semi-trucks to be plugged into them.

FIG. 5 is a three element thermoelectric module with inputs and outputs.

FIG. 6A is a top view of a thermoelectric module.

FIG. 6B is a front view of a thermoelectric module.

FIG. 6C is a back view of a thermoelectric module.

FIG. 7 is a diagram if thermoelectric modules connected in series and parallel arrangements.

FIG. 8A is a front view of a five partition HETEG device

FIG. 8B is a left side view of a five partition HETEG device

FIG. 8C is a right side view of a five partition HETEG device

FIG. 8D is a B-B view of a five partition HETEG device

FIG. 9 is orthogonal view of hot plate.

FIG. 10A is a top view of a two sided HETEG device without a by-pass system.

FIG. 10B is the bottom views of a two sided HETEG device with a by-pass system.

FIG. 10C is the back view of FIG. 10A.

FIG. 10D is the front view of FIG. 10A.

FIG. 10E is G-G view of FIG. 10D.

FIG. 10E is expanded view of a section in FIG. 10A.

FIG. 11A is a left side view of a roof type HETEG device.

FIG. 11B is a right side view of a roof type HETEG device.

FIG. 11C is a inside side view of a roof type HETEG device.

FIG. 12 is orthogonal view of components of mounting bracket.

FIG. 13 is orthogonal view of a three-channel EBS.

FIG. 14 is a functional diagram of a three-channel EBS.

FIG. 15 is a vane table of a three-channel EBS.

FIG. 16A is a sectional view of internal components of a four-channel four-channel EBS when it is OFF.

FIG. 16B is a sectional view of internal components of a four-channel four-channel EBS when it is ON.

FIG. 16C is a sectional view of internal components of a four-channel four-channel EBS when it is on AUTO.

FIG. 16D is a vane table of a four-channel EBS.

FIG. 17 a time plot of control algorithm result.

FIG. 18 is the control schematics of a HETEG system showing all components.

FIG. 19A is a voltage selector unit with two voltage outputs connected in series.

FIG. 19B is a voltage selector unit with two voltage outputs connected in parallel.

FIG. 19C is a voltage selector unit with four voltage outputs connected in parallel.

FIG. 19D is a voltage selector unit with four voltage outputs connected in parallel and series.

FIG. 19E is a voltage selector unit with two voltage outputs connected in parallel.

FIG. 20A is a side view of meshed wire tube sandwiched with fire resistant thermal insulation.

FIG. 20B is a top view of meshed wire tube sandwiched with fire resistant thermal insulation.

FIG. 20C is an orthogonal view of meshed wire tube sandwiched with fire resistant thermal insulation.

### DETAILED DESCRIPTION OF THE DISCLOSURE

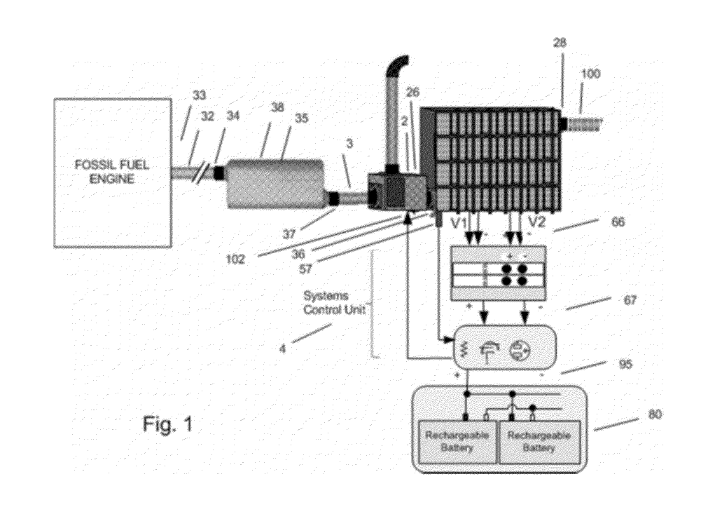

A complete exhaust heat thermoelectric generator (HETEG) system, shown in FIG. 1 is comprised of four essential components; each component has several embodiments. The components include a multi-element HETEG device 1, an Exhaust Bypass System (EBS) 2, a meshed wire exhaust pipe sandwiched with thermal insulation 3, and a Systems Control Unit 4.

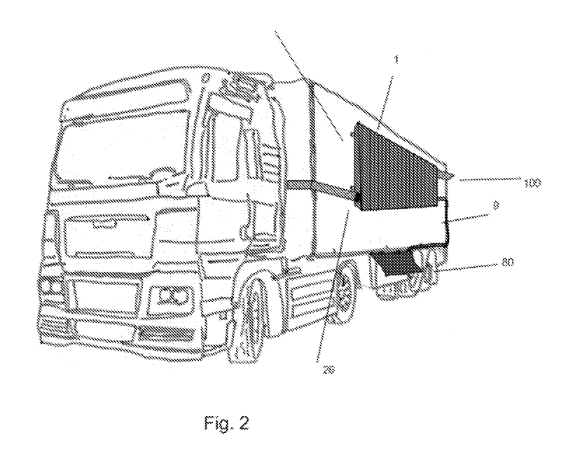

A multi-array HETEG device 1 is shown in FIG. 2 is mounted on the side of a truck.

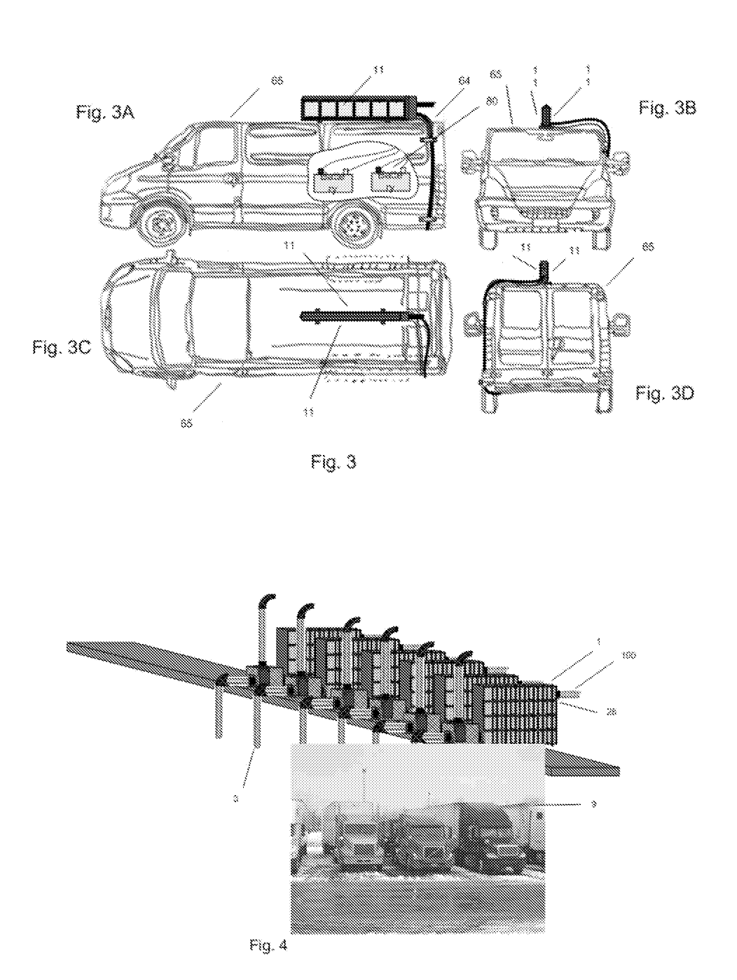

A HETEG device 1 mounted on the roof of a mini-van is shown in FIG. 3. FIG. 4 shows many HETEG devices mounted on a stationary location in readiness for idling trucks to plug their exhaust tails into them.

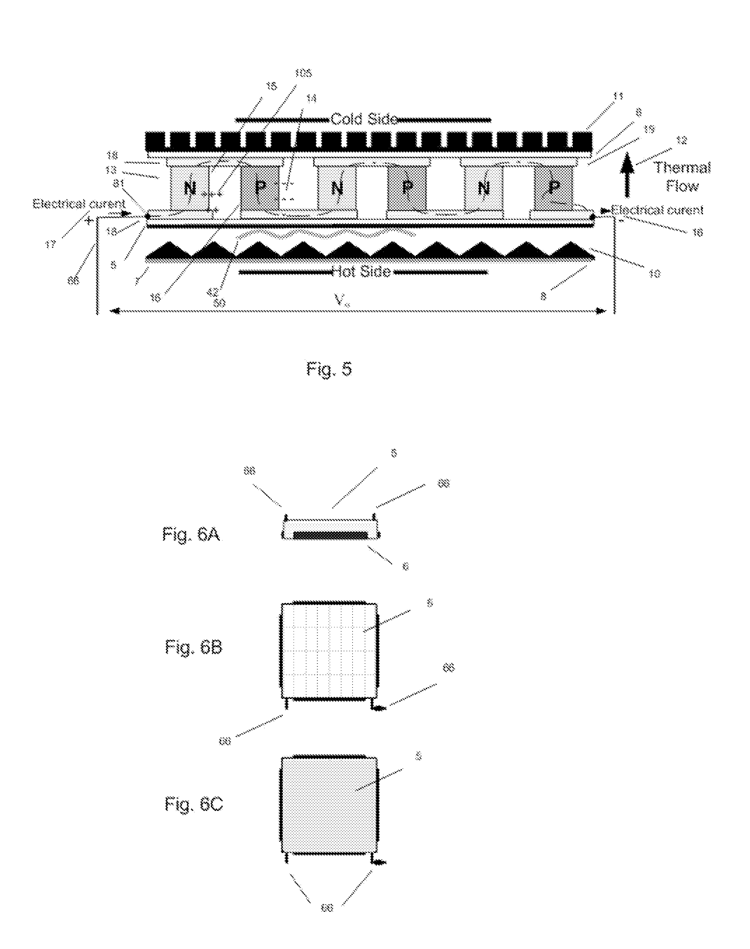

The inside construction of a HETEG element is shown in FIG. 5. FIG. 5 is a three element N-type and P-type module having a hot plate side 5 and a cold plate side 6. Hot plate side 5 is attached to exhaust channel 7. The outside wall of exhaust channel 7 is for mounting HETEG on a structure such as the roof of sides of a vehicle 9. The inside walls of exhaust channel 7 is constructed with a thermal insulated plate 10 shaped in saw-tooth pattern. The thermal insulated plate 10 is preferred to be of mica material to ensure durability and light weight. A heat dissipating plate 11 is securely attached to cold plate side 6. When exhaust heat 50 is applied to hot plate side 5, and simultaneously cold temperature is applied to heat dissipating plate 11, a thermal flow 12 takes place. Electrons 13 on the hot side 5 are more energized than on the cold side 6. Electrons 13 will flow from the hot side 5 to the cold side 6. In the N-type semiconductor 15, electron 105 flow will take place while in the P-type 16, electron holes 14 will flow. If an electrical load 80 is applied to the electrical terminals 66, an electric current 17 will flow through contact 18. Electric wires 66 and contact plates 18 are secured using a low resistance bonding method such as brazing at point 81.

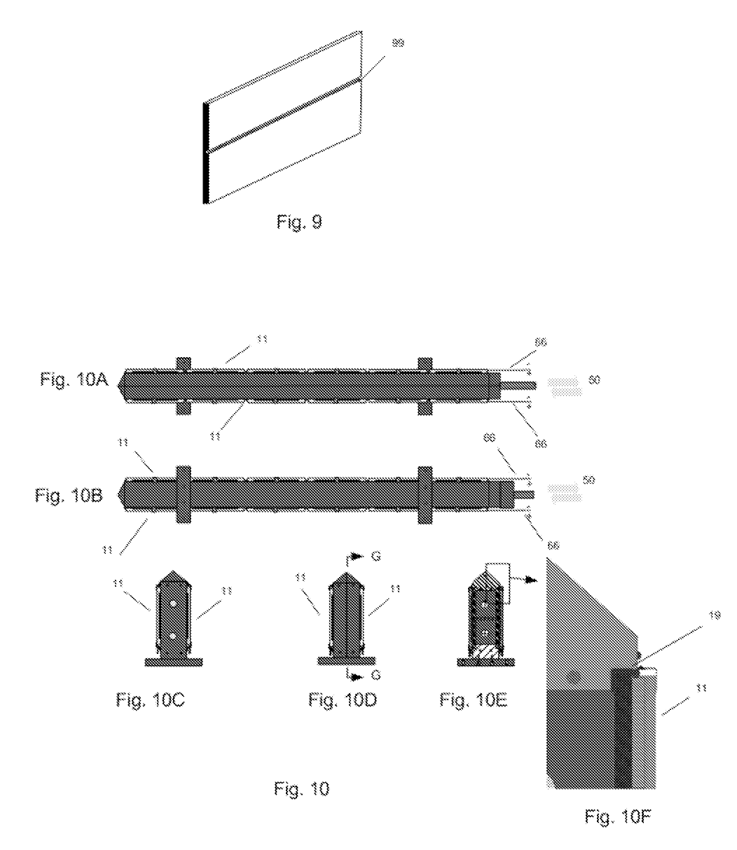

One construction detail of the hot plate side 5 is shown in FIG. 9. A slot 99 is cut along the length of hot plate 5.

Several views of a typical one module thermoelectric device are shown in FIG. 6A through FIG. 6C. The module has multiple elements. The module of FIG. 6 includes a hot plate side 5, a cold plate side 6 and a pair of electrical terminals 66.

When a thermoelectric module is used as a generator such as in this invention, hot temperature is applied to the hot plate side 5 and cold temperature is applied to the cold plate side 6. Temperature difference between the hot plate side 5 and cold plate side 6 is known as delta temperature, dT. For example, if temperature Tₕ is applied to hot plate side 5 and temperature Tc is simultaneously applied to cold plate side 6, then,

dT=Tₕ−T_{c}[°K.] (1)
T_{c} is less than Tₕ so that dT remains a positive number.

Using the three element thermoelectric module in FIG. 5 as an example, the output voltage, Vₒ is determined by,

Vₒ=Sₘ*dT (2)
Where,
Sₘ is Module's average Seebeck coefficient [volt/°K.]. Sₘ is also a function of figure of merit zT of the material.

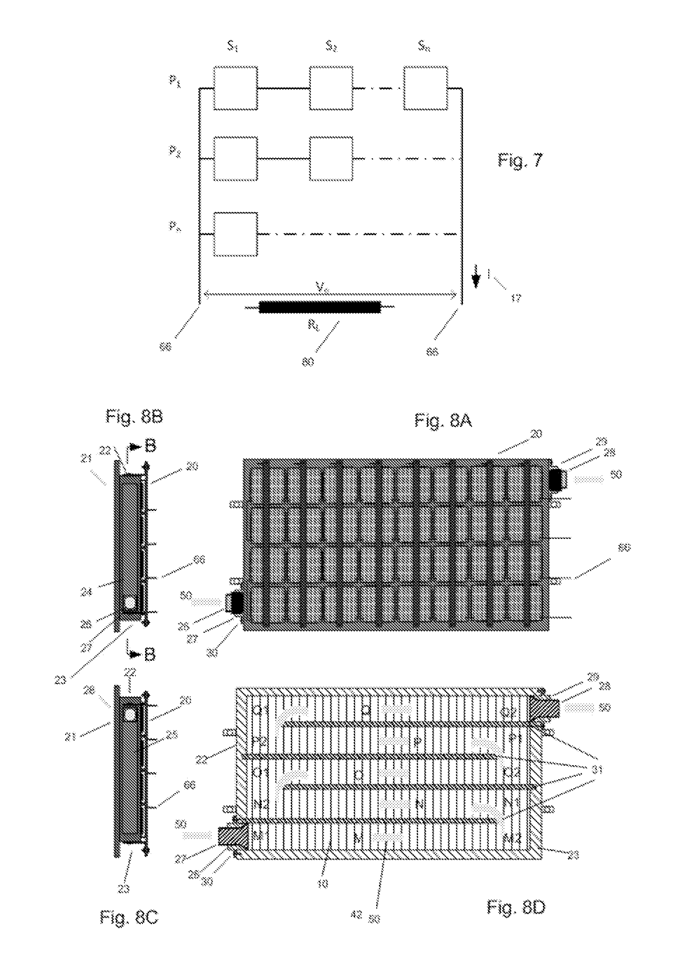

FIG. 7 has a combination of series and parallel arrangements, therefore, considering load resistance R_{L} and output current I, output voltage is,

Vₒ=I*(Rₘ+R_{L}) (3)
Where,
Rₘ is Module's average resistance [ohms] and a function of the thermoelectric module.

Output current, I is,

$$I = \frac{{N}_{s} * {S}_{m} * d T}{( \frac{{N}_{s}}{{N}_{p}} ) {R}_{m} + {R}_{L}} \qquad ( 4 )$$

Output power [watts] is therefore,

$${P}_{o} = \frac{{N}_{T} * {( {S}_{m} * d T )}^{2}}{4 {R}_{m}} \qquad ( 5 )$$

Where,
S₁ is first series element.
S₂ is second series element.
Sₙ is n^{th} series element.
P₁ is first parallel path.
P₂ is second parallel path.
Pₙ is n^{th} parallel path.
Nₛ is the total number of series arrangements.
N_{T} is total number of elements in the array.
Nₚ is total number of parallel paths.

### OTHER HETEG EMBODIMENTS

One embodiment: HETEG device that can be installed on the periphery of a train.

One embodiment: HETEG device that can be installed on the periphery of a plane.

One embodiment: HETEG device that can be installed in the ballast of a ship.

One embodiment: HETEG device that can be installed on a chimney.

Other embodiment may not have been listed here.

A two dimensional view of the inside components of the HETEG device 1 of FIG. 2 is further shown in FIG. 8A through 8D. The FIG. 8 device has six sides in the shape of a box. The sides include a first side 20, a second side 21, a third side 22 and a forth side 23. The second side 21 is on opposite of first side 20. Second side 21 is the anchor side for installation to the side of a vehicle 9. HETEG shown in FIG. 8 also includes a third side 22 and a forth side 23. Third side 22 and forth side 23 are top and bottom respectively of HETEG.

FIG. 8 HETEG device further includes a fifth side 24 and a sixth side 25 which are left and right sides respectively of the HETEG device. At the bottom location of fifth side 24 is an exhaust heat inlet pipe 26 securely attached to inlet hole 27. At the top location of sixth side 25, exhaust heat outlet pipe 28 is securely attached to outlet hole 29. A flow of exhaust heat 50 leaves fossil fuel exhaust pipe 28 and enters HETEG device through exhaust heat inlet pipe 26 and leaves through outlet pipe 28. Exhaust heat inlet pipe 26 and outlet pipe 28 are preferably made of heat resisting or other thermal insulating materials.

Outside shape of fifth side 24 is aerodynamically curved to prevent wind drag when vehicle is in motion.

Third side 22, forth side 23, fifth side 24 and sixth side 25 of the HETEG device as shown in FIG. 8 are the outside surfaces.

First side 20 has two layers, a first layer 94 and a second layer 97. First layer 94 is the same as hot plate side 5. Second layer 97 is the same as the heat dissipating plate 11. Thermoelectric elements 106 are sandwiched between hot plate side 5 and heat dissipating plate 11.

As shown in FIG. 8D, first side 20, second side 21, third side 22, forth side 23, fifth side 24 and sixth side 25 are securely attached together at their corners with screws 30. None flammable heat resisting compound 19 as depicted in FIG. 1 OF is spread between the corner joints to ensure a tight fit. The non-flammable heat resisting compound 19 is applied and allowed to dry to form a solid heat escape barrier.

The inside compartment of HETEG device is shown in FIG. 8D is partitioned into multi-layer heat chambers. The chambers are a first chamber M, a second chamber N, a third chamber O, a forth chamber P and a fifth chamber Q. Each chamber partition creates a heat path that maximizes the effect of heat on its portion of hot plate 5. The cross sectional area of each chamber partition is equivalent to or more than the cross sectional area of the exhaust pipe that conveys the exhaust heat 50. The chamber cross sectional area is chosen to prevent exhaust back stroke on fossil fuel engine. Each heat chamber partition M, N, O, P and Q is separated by partition separator plate 31.

Partition separator plate 31 is preferably made of a rigid flat heat resisting material or other thermal insulating materials. Each partition separator 31 slides into slot 99 of hot plate 5.

FIG. 1 is a general overview of the HETEG system showing all electrical and mechanical connections. The exhaust pipes that conveys exhaust heat 50 from fossil fuel engine into HETEG device includes a first exhaust pipe 32 a second exhaust pipe 3 and a third exhaust pipe 36.

Exhaust heat 50 leaves the exhaust manifold 33 through first exhaust pipe 32. First exhaust pipe 32 connects to inlet pipe 34 of exhaust cylinder 35. Second exhaust pipe 3 connects to outlet pipe 37 of exhaust cylinder 35 and to exhaust bypass system (EBS) 2. Third exhaust pipe 36 connects EBS 2 to exhaust heat inlet pipe 26.

First exhaust pipe 32, second exhaust pipe 3 and third exhaust pipe 36 are all made with meshed wire sandwiched with thermal insulation material 98 as in FIG. 20 to prevent any heat loss along its path. Meshed wire sandwiched with thermal insulation material 98 is designed to be light in weight. Exhaust cylinder 35 is insulated with heat resisting material 38 in order to prevent any heat loss. A preferred heat resisting material is mica sheets.

FIG. 20A through 20C show a preferred embodiment of a thermally insulated light weight exhaust pipe 3 construction. A cross sectional view of the thermally insulated robust light weight pipe 3 is shown in FIGS. 20B and 20C. Exhaust pipe 3 includes an inner tube 39, meshed wire 40 sandwiched with thermal insulations 41. The meshed wire 40 also serves as reinforcement for durability and robustness Inner tube 39 is polished with ceramic coating to prevent accumulation of smoke soot.

Referring now to the invention in more details according to FIG. 8D, there is shown exhaust heat 50 entering the HETEG device through exhaust heat inlet pipe 26 and travels into chamber partition M at point M1. Exhaust heat 50 continues its journey in chamber partition M to the end of chamber partition M at point M2. At point M2, exhaust heat 50 curves to chamber partition N at point N1. Exhaust heat 50 continues from chamber partition N to O and to chamber partition P and further to chamber partition Q. At point Q2, exhaust heat 50 leaves HETEG device through outlet pipe 28 and into the atmosphere.

As exhaust heat 50 enters each chamber partition M, N, O, P and Q, it is incident on a saw-tooth wall fins 10. The saw-tooth shape of the wall fins 10 causes the entrant exhaust heat 50 to undulate. As exhaust heat 50 undulates, it bounces on hot plate 5, causing hot plate 5 to absorb all the exhaust heat 50 energy. Saw-tooth wall fin 10 is made of light weight heat resisting material such as mica.

Exhaust heat undulation 42 inside chamber partitions M, N, O, P and Q serve two purposes. Firstly, exhaust heat 50 bounces on hot plate 5 as undulation takes place. Impact of the bounce increases the heat on hot plate 5. Secondly, exhaust heat undulation 42 cause exhaust heat 50 to spend additional time inside each chamber partition M, N, O, P and Q. The more time exhaust heat 50 spends inside chamber partitions M, N, O, P and Q, the more hot plate 5 absorbs the heat energy.

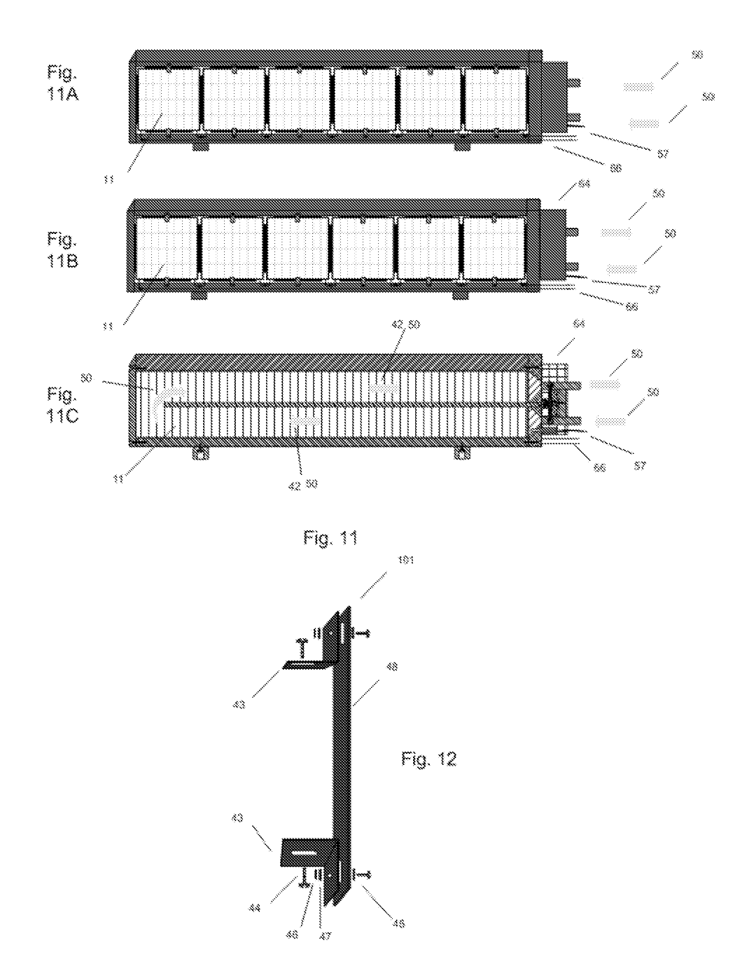

To ensure a secure attachment of thermoelectric modules onto hot plate 5, a securing bracket assembly 101 is used. The securing bracket assembly 101 shown in FIG. 12 includes a pair of bracket elbows 43 and a pair of first fastening screws 44, second pair of fastening screws 45, a pair of adjustment nut 46, a pair of space washer 47 and a rectangular bar 48. The quantity of securing bracket assembly 101 is dependent on the number and size of thermoelectric modules in a HETEG assembly.

One of bracket elbow 43 is used at each end of rectangular bar 48. Rectangular bar 48 has one hole in the center at each end where second fastening screw 45 passes through. First fastening screw 44 serve two purposes; they secure bracket elbow assembly 43 unto the thermally insulated outside frames of the HETEG device. First fastening screw 44 also ensure that necessary adjustment is made to maintain permanent and secure physical contact between hot plate 5 and heat dissipating plate 11.

Bracket elbow assembly 101 is preferably made with high temperature heat resistant plate preferably mica bars.

HETEG embodiment shown in FIG. 2 receives its cold side temperature Tc, when vehicle 9 is in motion. As vehicle 9 moves, heat dissipating plate 11 cuts through passing wind 49. In the process, cold side plate 6 is cooled by wind gust. During winter seasons, the cold side plate 6 is colder by wind chill factor.

A HETEG device installed in a stationary location such as seen in FIG. 4 can is cooled by ambient temperature or by a pool of water circulating on heat dissipating plate 11.

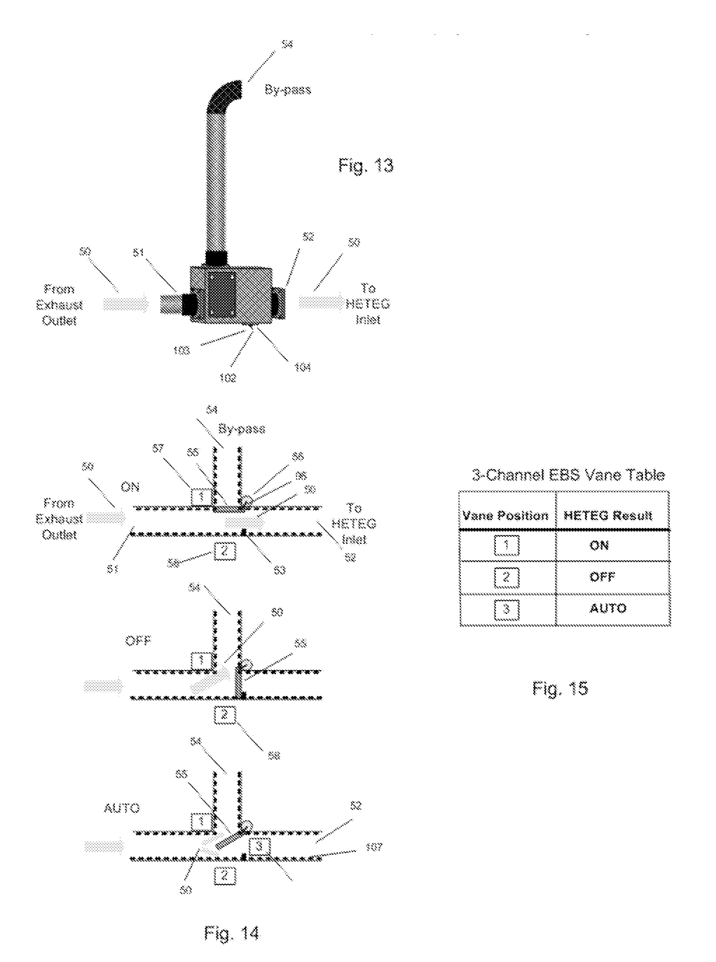

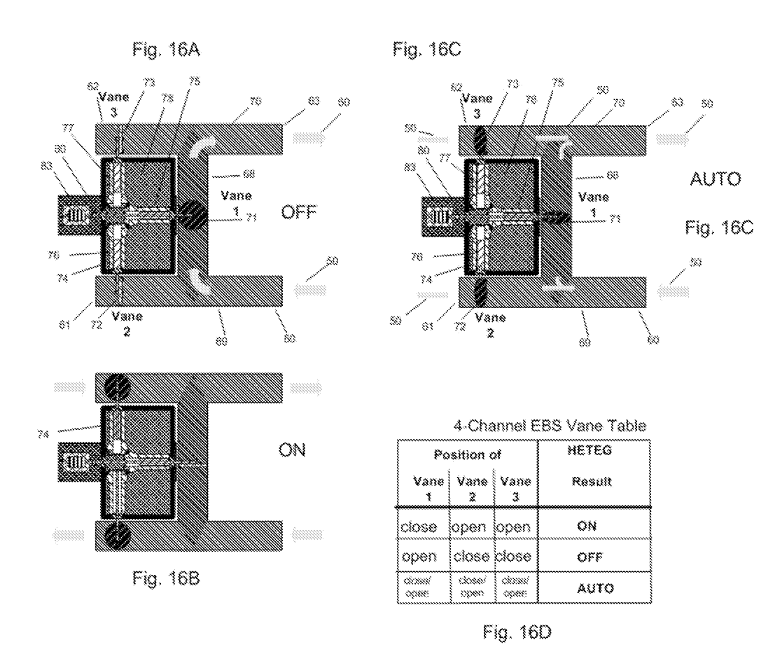

One essential embodiment of the HETEG system is the Exhaust By-pass System (EBS) 2. The inside lining 107 of EBS 2 is a heat resistant material such as mica. The outside material of EBS may be any rigid material such as metal sheet. EBS 2 can be of three or four channels. The number of EBS 2 channels depends on the HETEG configuration it is serving. Construction details of a three-channel EBS 2 are shown in FIG. 13. The inner components and functions of a three-channel EBS 2 are shown in FIG. 14. A four-channel EBS 2 is shown in FIG. 16.

For example, when exhaust heat inlet pipe 26 and exhaust outlet pipes 28 are in close proximity as with the HETEG device shown in FIG. 10 and FIG. 11, a four-channel EBS 2 is used. Alternatively, when the physical location of exhaust heat inlet pipe 26 and exhaust outlet pipes 28 are far apart from one another as in FIG. 1, a three-channel EBS 2 is desired.

When a HETEG device is installed, it may be necessary to turn it OFF by diverting exhaust heat 50 away from chamber partitions M, N, O, P and Q. This can be achieved by installing an EBS 2 on the exhaust line. EBS 2 is also used to protect the thermoelectric elements from damage when excessive heat, detected by a temperature sensor 57, is present in chamber partition M.

There are several locations where EBS 2 can be installed. In FIG. 1, the three-channel EBS 2 is installed between exhaust cylinder 35 and HETEG device. EBS is ON is when exhaust heat 50 enters the HETEG device and the device functions as a generator. OFF is when exhaust heat 50 does not enter the HETEG device and no voltage is generated. EBS 2 and its controller can regulate the quantity of exhaust heat 50 that enters HETEG to maintain a constant voltage. EBS 2 is in the AUTO mode when it is automatically controlling the output voltage of a HETEG device.

The three-channel EBS 2 shown in FIG. 14 has a first channel 51, a second channel 52, a third channel 54 and a vane 55. First channel 51 connects to exhaust cylinder 35. Second channel 52 connects to the inlet pipe 26 and third channel 53 is a bypass exhaust pipe 54 for releasing exhaust heat 50 into the atmosphere. The internal construction of EBS 2 includes vane 55 and a vane support 111. Vane 55 is securedly attached to a rod 96. Rod 96 is attached to pivot at the intersection 56 between second channel 52 and third channel 54. Vane 55 operates by flapping between first position 108 and second position 109. When vane 55 is in first position 108, exhaust heat 50 will only travel into second channel 52 and into HETEG device. This is the ON or DEFAULT position because the HETEG in operating continuously. When vane 55 is in second position 109, exhaust heat will only travel into third channel 54 preventing HETEG from operating. This is the OFF position because HETEG is not generating any voltage. When vane 55 is between first position 108 and second position 109, such as in position 110, a proportion of exhaust heat 50 enters second channel 52 and another proportion enters third channel 53. This is the AUTO mode because HETEG output is regulated automatically by controller 59 based on delta temperature dT. Output temperature Vₒ is relatively constant in the AUTO mode.

When the three-channel EBS 2 is in the ON position, vane 55 rests on vane support 111. The contact between vane 55 and vane support 111 ensures that no exhaust heat 50 escapes into second channel 52.

A vane table is shown in FIG. 15. FIG. 15 table corresponds to the operation of the three-channel EBS 2.

The three-channel EBS 2 shown in FIG. 13 also includes a toggle switch 102. Toggle switch 102 is used to by-pass the operations of the algorithm. At one position 103, toggle switch 102 will allow control algorithm 84 to be functional. In another position 104, toggle switch 102 will turn off control algorithm 84.

The inside details of a four-channel EBS 64 is shown in FIGS. 16A and 16B. Functional use of a four-channel EBS 2 is depicted in FIG. 3 and FIG. 11. A four-channel EBS 2 shown in FIG. 16 has four-channels and three vanes. A first channel 60 connects to exhaust tail 37 of a vehicle 65. A second channel 61 connects to exhaust inlet pipe 26 of a HETEG device. A third channel 62 connects to exhaust outlet 28 of a HETEG device. A forth channel 63 allows exhaust heat 50 to escape to the atmosphere. First channel 60 and second channel 61 is constructed with one first continuous pipe 69. Third channel 62 and forth channel 63 is made of another second continuous pipe 70. An exhaust bypass pipe 68 perpendicularly connects the middle points of the first continuous pipe 69 and second continuous pipe 70. First channel 60, second channel 61, third channel 62 and forth channel 63 are pipes made with meshed wire exhaust pipe sandwiched with thermal insulation 98.

Further describing the functionality of the four-channel EBS 64 of FIG. 16, a first vane 71 is attached to and operates in the middle of exhaust by-pass 68. A second vane 72 operates inside the second channel 61 and a third vane 73 operates inside the third channel 62. The diameter of each vane is slightly less than the diameter of the channel it is serving; therefore, an unrestricted but tight movement of vanes is taking place.

The four-channel EBS 64 also includes a spur gear housing and assembly 74. The spur gear housing assembly 74 contains three spur gears, namely, a first spur gear 75, a second spur gear 76, and a third spur gear 77. Spur gear housing assembly 74 has upper housing cover and lower housing cover. Spur gear housing assembly 74 also contains lubricating agent 78 to cause first spur gear 75, second spur gear 76 and third spur gear 77 to rotate freely and avoid wear during operation. First spur gear 75 is installed horizontally inside spur gear box housing 74. Second spur gear 76 and third spur gear 77 are installed vertically and opposite of each other. Second spur gear 76 and third spur gear 77 are also installed perpendicularly to first spur gear 75. The teeth of all three spur gears 75, 76 and 77 are engaged with each other as shown in FIG. 16. First vane 71 is attached to first spur gear 75. Second vane 72 is attached to second spur gear 76. Third vane 73 is attached to third spur gear 77.

Using FIG. 16B to describe the ON position of the four-channel EBS 64, first vane 71 is perpendicular with the walls of bypass pipe 68, thus restricting the flow of exhaust heat 50 from first channel 60 to forth channel 63. Second vane 72 is parallel with second channel 61, thereby allowing exhaust heat 50 to travel from first channel 60 to second channel 61. Also, third vane 73 is parallel with third channel 62, thereby allowing exhaust heat 50 to flow from HETEG exhaust outlet 100 to forth channel 63.

Using FIG. 16A to describe the OFF position of the four-channel EBS 64, first vane 71 is parallel with the walls of bypass pipe 68, thus allowing the flow of exhaust heat 50 from first channel 60 to forth channel 63. Second vane 72 is perpendicular with second channel 61, thereby preventing exhaust heat 50 from travelling from first channel 60 to second channel 61. Also, third vane 73 is perpendicular with third channel 62, thereby preventing exhaust heat 50 from traveling from HETEG exhaust outlet 100 to forth channel 63.

Using FIG. 16C to describe the AUTO position of the four-channel EBS 64, first vane 71 is partially blocking bypass pipe 68, thus allowing the flow of some quantity of exhaust heat 50 from first channel 60 to forth channel 63. Second vane 72 is partially blocking second channel 61, thereby preventing some exhaust heat 50 from travelling from first channel 60 to second channel 61. Also, third vane 73 is partially blocking third channel 62, thereby preventing some exhaust heat 50 from traveling from HETEG exhaust outlet 100 to forth channel 63.

In FIG. 16D, a four-channel vane table that describes the inputs and impacts of a four-channel EBS 64 is shown. First column of vane table are vane positions of first vane 71, second vane 72 and third vane 73. Second column of vane table is HETEG output in response to positions of first vane 71, second vane 72 and third vane 73. The responses are ON, OFF and AUTO results.

Continuing on FIG. 16, first spur gear 75 is attached to a control mechanism, preferably a position solenoid 83. A control algorithm 84 embedded into System Control Unit (SCU) 4 and temperature sensor 87, determines the operation of position solenoid 83. Position solenoid 83 controls rod 96. Rod 96 controls first vane 71, second vane 72 and third vane 73. First vane 71, second vane 72 and third vane 73 controls the flow of exhaust heat 50 inside first channel 60, second channel 61 and third channel 62 respectively.

As exhaust heat 50 enters hot plate 5, temperature sensor 57 reads the quantity of heat on hot plate 5. Temperature sensor value T_{h sensed} 86 is relayed to control algorithm 84. Control algorithm 84 processes sensed temperature Tₕ_{_{—}}_{sensed} 86 and decides how and when to operate position solenoid 83.

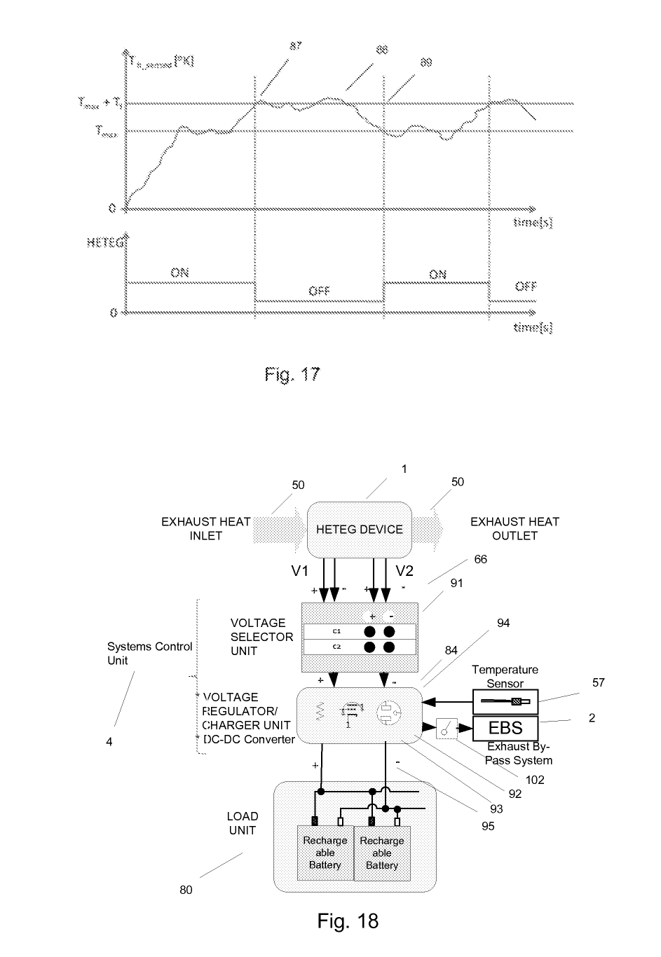

An example of a temperature sensor 57 reading during a typical operation is shown in FIG. 17. Top graph is a time plot of sensed temperature values in relation with operating points. The essential operating point is the maximum safe operating temperature of HETEG. The bottom graph is a time plot of HETEG output due to the operation of position solenoid 83.

Continuing with FIG. 17, let Tₘₐₓ+T₁ represent the maximum safe operating temperature of our HETEG device. Maximum operating temperature is separated into two quantities, Tₘₐₓ and T₁ in order to produce an efficient control algorithm 84. T₁ is introduced to prevent sporadic ON and OFF toggling when temperature sensor 57 is doddering above 575 and below Tₘₐₓ. Temperature sensor 57 is installed near chamber partition M.

When fossil fuel engine is running and exhaust heat 50 is passing through HETEG device, temperature sensor 57 begins to measure the temperature of exhaust heat 50. HETEG is in the ON state at this initial stage. When sensed temperature Tₕ_{_{—}}_{sensed} 86 reaches or exceeds Tₘₐₓ+T₁ as shown in point 87 in FIG. 17, HETEG is switched to OFF by the operation of position solenoid 83. Exhaust heat 50 now passes through by-pass exhaust 68 at which time Tₕ_{_{—}}_{sensed} 86 begins to cool down as shown by point 88. When T_{h sensed} drops to below Tₘₐₓ as indicated by point 89, position solenoid 83 is de-energized and HETEG is turned ON.

A stepper motor 90 can be used in place of a position solenoid 83 to provide operations of rod 96. The operation thus causes HETEG to go ON or OFF. A stepper motor 90 also provides a continuous control of rod 96 for AUTO operations.

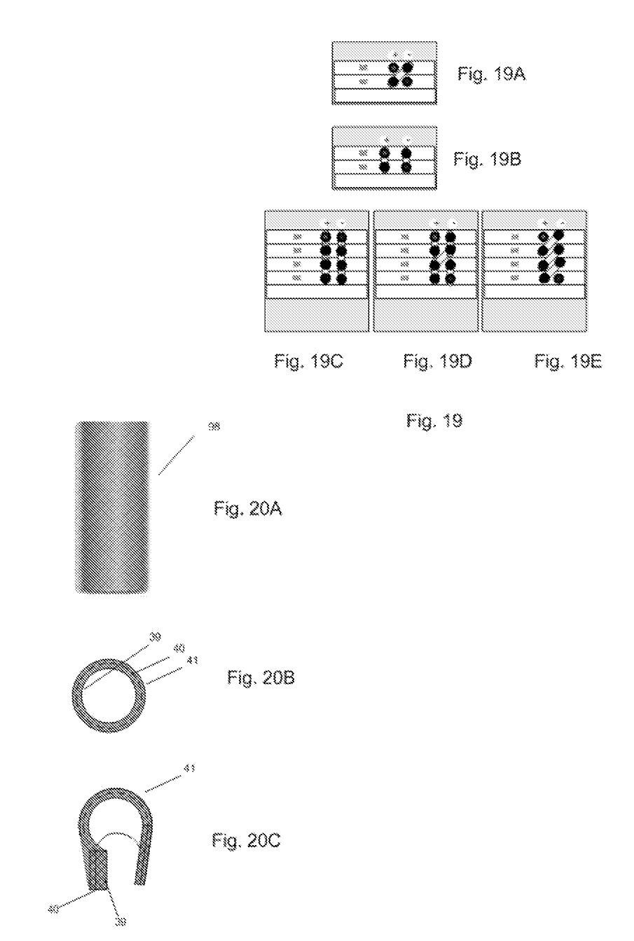

One preferred embodiment of the HETEG system is the Systems Control Unit (SCU) 4 is displayed in FIG. 18. A SCU 4 includes a voltage selector unit 91, a DC-DC converter unit 92, a control algorithm 84 and a voltage charger/regulator unit 93. Voltage selector unit 91 is used to arrange HETEG output voltage V₁, V₂, V₃ and V₄ into series and parallel combinations as shown in FIG. 19. FIG. 19A shows V₁ and V₂ connected in series. FIG. 19B is V₁ and V₂ connected in parallel. FIG. 19C, 19D and 19E depict V₁, V₂, V₃ and V₄ 66 connected in series and parallel arrangements. Series and parallel arrangements ensure that the desired voltage is achieved. Output voltages V₁, V₂, V₃ and V₄ 66 from HETEG device serve as inputs to voltage selector unit 91.

One preferred embodiment of the HETEG system is a DC-DC converter 92 shown in FIG. 18. Converter 92 receives input voltage V₁, V₂, V₃ and V₄ 67 provided by voltage selector unit 91. Voltages 67 are conditioned and sent out as V₁, V₂, V₃ and V₄ 95. An electrical load 80 such as a rechargeable battery is connected across V₁, V₂, V₃ and V₄ 95.

While the invention has been taught with specific reference to the above embodiments, a person having ordinary skill in the art will recognize that changes can be made in form and detail without departing from the spirit and the scope of the invention. The described embodiments are to be considered in all respects only as illustrative and not restrictive. All changes that come within the meaning and range of equivalency of the claims are to be embraced within their scope. Combinations of any of the methods, systems, and device described hereinabove are also contemplated and within the scope of the invention.

I claim:

1. A voltage generating system comprising: an exhaust heat source; an exhaust heat thermoelectric generator (HETEG); an exhaust by-pass system; (EBS) a meshed wire exhaust pipe sandwiched with fire resistant thermal insulation; and, a system control unit.

2. A voltage generating system as in claim 1, wherein said HETEG has a plurality of thermoelectric modules and said thermoelectric modules have plurality of N-type and P-type semiconductors; and a plurality of hot plates and a plurality of cold plates and a plurality of pair of electrical terminals; said hot plates are mounted on one large hot plate and said cold plates are mounted on one large heat dissipating plate and said plurality of thermoelectric modules are assembled in a tight proximity array and said plurality of N-type and P-type semiconductors are sandwiched between said large hot plate and said heat dissipating plate.

3. A voltage generating system as in claim 1, wherein said HETEG device is installed on the periphery of a train, and when said train is in motion, said heat dissipating plate is cooled by wind gust; said HETEG device is installed on the periphery of a plane, and when said plane is in motion, said heat dissipating plate is cooled by wind gust; said HETEG device is installed in a ship, said heat dissipating plate is cooled by ballast water; said HETEG device is installed on the periphery of a chimney, said heat dissipating plate is cooled by ambient temperature.

4. A voltage generating system as in claim 1, wherein said HETEG has a heat chamber and said heat chamber is in the form of a hollow box having a plurality of partitions; a first side and a second side and a third side and a forth side and a fifth side and a sixth side; said first side is the same as said large hot plate and said second side is opposite said first side and said second side is the mounting base; said third and forth sides are the top and bottom covers respectively of said heat chamber, and said fifth and sixth sides are the left end and right end respectively of said heat chamber, and said second side and said third side and said forth side and said fifth side and said sixth side have fire resistant thermal insulated inside lining preferably made of mica, said inside lining on said second side has an uneven surface such as saw-tooth surface; said fifth side have an exhaust inlet pipe affixed to it and said sixth side have an exhaust outlet pipe affixed to it.

5. A voltage generating system as in claim 4, wherein said mounting base is used to secure said HETEG on the periphery of a vehicle such as the sides; two HETEG devices are clamped together at their said mounting bases and a new mounting base is established from said forth sides for mounting on vehicle periphery such as roof.

6. A voltage generating system as in claim 1 or 4 wherein said heat source is emanating from exhaust tail of a fossil fuel engine and producing exhaust heat, and said exhaust tail is connected into said exhaust inlet pipe, and said saw-tooth has peaks and valleys in parallel with direction of said exhaust heat flow and said exhaust heat is traveling into said heat chamber and undulates and perturbed as a result of said uneven surface such as saw-tooth surface, and said undulation causes said exhaust heat to forcefully land on said large hot plate and said large hot plate absorbs said exhaust heat and said perturbation causing said exhaust heat to spend more time (delay) in said heat chamber and said undulation and said delay causing hot plate to get hotter and said exhaust heat escapes into atmosphere through said outlet pipe.

7. A voltage generating system as in claim 5, wherein said HETEG device is installed on the periphery of a vehicle such as the roof, and when said vehicle is in motion, said heat dissipating plate is cooled by wind gust.

8. A voltage generating system as in claim 5, wherein said HETEG device is installed in a stationary location for idling vehicles to connect their exhaust tail pipes, said exhaust tail pipe connection causing exhaust heat to enter said exhaust chamber and increasing the temperature of said hot plate and said heat dissipating plate is cooled by ambient temperature or pool of water.

9. A voltage generating system as in claim 2 wherein said hot plate temperature and said heat dissipating plate are causing temperature difference, said temperature difference causing electron to flow in said N-type and said P-type semiconductors, said electron flow generates an output voltage across said plurality of electrical terminals, said output voltage is connected across an electrical load and an electrical current flows resulting in output power represented by the general formula (N.sub.T*(S.sub.m*dT)**2)/(4*R.sub.m), where N is the total number of thermoelectric modules, dT is the temperature difference between said hot and said cold plates and R is the average Seebeck coefficient of the thermoelectric module.

10. A voltage generating system as in claim 1 or 6, wherein said EBS has: three channels; an exhaust inlet channels for accepting said exhaust heat from said exhaust tail, an outlet channel for accepting exhaust heat into HETEG, and a by-pass channel for allowing said exhaust heat to escape into the atmosphere;
a position solenoid or stepper motor;
a by-pass switch; and a vane;
said position solenoid or stepper motor is controlled by a control algorithm; said position solenoid or stepper motor is securedly attached to said vane, and said vane control the flow of said exhaust heat into HETEG through said inlet channel or away from HETEG through said outlet channel.

11. A voltage generating system as in claim 1 or 6, wherein said EBS has: four channels; an exhaust inlet channels for accepting said exhaust heat from said exhaust tail, a HETEG inlet channel for accepting exhaust heat into HETEG, a HETEG outlet channel for accepting exhaust heat from HETEG outlet and a by-pass channel for allowing said exhaust heat to escape into the atmosphere;
a position solenoid or stepper motor;
a by-pass switch; and plurality of vanes, a first vane, a second vane and a third vane;
said position solenoid or stepper motor is controlled by a control algorithm; said position solenoid or stepper motor is securedly attached to a first spur gear; teeth of said first spur gear is engaged with both teeth of a second spur gear and teeth of a third spur gear; and
one end of said first spur gear is attached to said position solenoid or stepper motor; other end of said first spur gear is attached to said first vane; other end of said second spur gear is attached to said second vane; other end of said third spur gear is attached to said third vane; and,
said first vane and said second vane and said third vane control the flow of said exhaust heat into HETEG through said inlet channel or away from HETEG through said outlet channel.

12. A voltage generating system as in claim 10 wherein said by-pass switch allows position solenoid or stepper motor to be energized to one position which does not allow flow of said exhaust heat into HETEG, or to another position which allows the flow of said exhaust heat into HETEG.

13. A voltage generating system as in claim 1 characterized by: a meshed wire exhaust pipe sandwiched with fire resistant thermal insulation, said meshed wire exhaust pipe sandwiched with fire resistant thermal insulation has an inner tube for conveying said exhaust heat from said exhaust pipes into said heat chamber and a meshed wire wrapped on outer surfaces of said inner tube and a thermal insulated material wrapped on said meshed wire; said inner tube and said thermal insulated material are preferably made of mica; and inside surfaces of said inner tube is glazed such as with ceramic coating to avoid accumulation of exhaust soot.

14. A voltage generating system as in claim 1 or 9, wherein said system control unit has a voltage selector unit, a voltage regulator unit and charger unit; said voltage selector unit has a plurality of electrical terminals for connecting said voltage in series or parallel combinations;
said voltage regulator unit conditions said output voltage by smoothening out peaks and valleys of said output voltage; a control algorithm, said algorithm determines when to turn said position solenoid or stepper motor to ON or OFF or AUTO according to a sensed values of a temperature sensor; and, a charger unit for charging uncharged batteries; said charger unit accepts input voltage from said voltage regulator, and said charger unit modifies said output voltage to charge uncharged batteries.
